(19) United States
(12) Patent Application Publication
(10) Pub. No.: US 2025/0336844 A1
(43) Pub. Date: Oct. 30, 2025

(54) Semiconductor Package and Method

(71) Applicant: Taiwan Semiconductor Manufacturing Co., Ltd., Hsinchu (TW)

(72) Inventors: Shu-Shen Yeh, Taoyuan City (TW); Chien Hung Chen, Taipei (TW); Ming-Chih Yew, Hsinchu (TW); Po-Yao Lin, Zhudong Township (TW); Shin-Puu Jeng, Hsinchu (TW)

(21) Appl. No.: 19/258,102

(22) Filed: Jul. 2, 2025

Related U.S. Application Data
(62) Division of application No. 17/663,683, filed on May 17, 2022.

(51) Int. Cl. H01L 23/00; H01L 21/56; H01L 23/498

(52) U.S. Cl. CPC H01L 23/562; H01L 21/563; H01L 23/49822; H01L 24/32; H01L 24/73; H01L 2224/32225; H01L 2224/73204

(57) ABSTRACT

A semiconductor package including a recessed stiffener ring and a method of forming are provided. The semiconductor package may include a substrate, a semiconductor die bonded to the substrate, an underfill between the semiconductor die and the substrate, and a stiffener ring attached to the substrate, wherein the stiffener ring encircles the semiconductor die in a top view. The stiffener ring may include a recess that faces the semiconductor die.

### PRIORITY CLAIM AND CROSS-REFERENCE

This application is a divisional of U.S. patent application Ser. No. 17/663,683, filed on May 17, 2022, which application is hereby incorporated herein by reference.

### BACKGROUND

The formation of integrated circuits includes forming integrated circuit devices on semiconductor wafers, and then sawing the semiconductor wafers into device dies. The device dies may be bonded to package components such as interposers, package substrates, printed circuit boards, or the like. To protect the device dies and the bonding structures that bond a device die to a package component, an encapsulant such as a molding compound, an underfill, or the like, may be used to encapsulate the device dies.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-3, 4A, 4B, 4C, 4D, 5-8, 9A, 9B, and 9C illustrate the cross-sectional views and top views of intermediate stages in the formation of a semiconductor package including a stiffener ring in accordance with some embodiments.

FIG. 10 illustrates a process flow for forming a semiconductor package in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A semiconductor package with a recessed stiffener ring and the method of forming the same are provided. In accordance with some embodiments of the present disclosure, one or more semiconductor dies and/or semiconductor packages are bonded to an underlying substrate. Underfill is formed between the one or more semiconductor dies or semiconductor packages and the substrate. The recessed stiffener ring is placed on the underlying substrate and encircles the one or more semiconductor dies and/or semiconductor packages. The recessed stiffener ring has a reduced stiffness in the recessed portion so that it reduces cracking and/or delamination of the corner regions of the underfill adjacent the recessed portion. The reduction of cracking and/or delamination of the underfill leads to better long-term reliability of the semiconductor package.

Embodiments discussed herein provide examples to enable making and using the subject matter of this disclosure, and a person having ordinary skill in the art will readily understand modifications that can be made while remaining within contemplated scopes of different embodiments. Throughout the various views and illustrative embodiments, like reference numbers are used to designate like features. Although method embodiments may be discussed as being performed in a particular order, other method embodiments may be performed in any logical order.

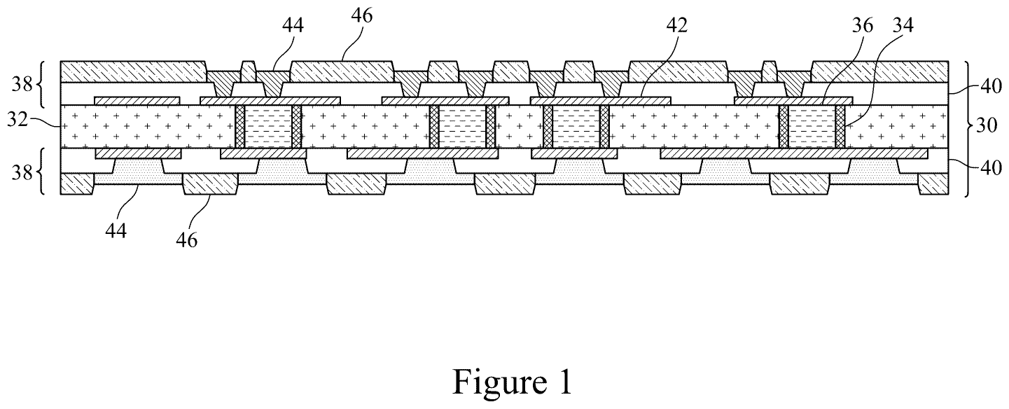

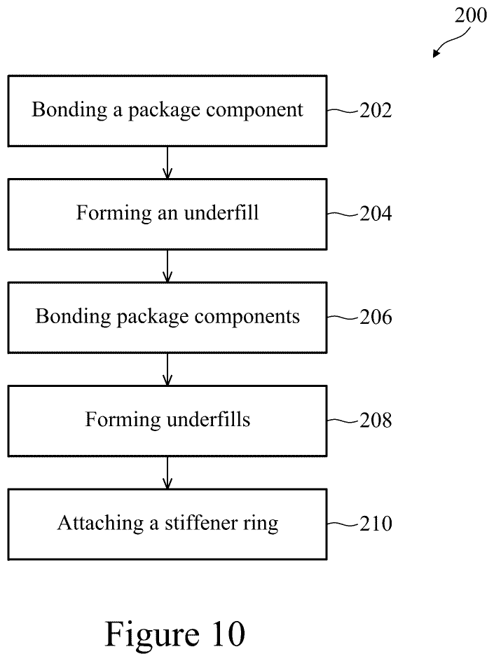

FIGS. 1-3, 4A, 4B, 4C, 4D, 5-8, 9A, 9B, and 9C illustrate the cross-sectional views and top views of intermediate stages in the formation of a semiconductor package including a stiffener ring in accordance with some embodiments. The corresponding processes are also reflected schematically in the process flow shown in FIG. 10.

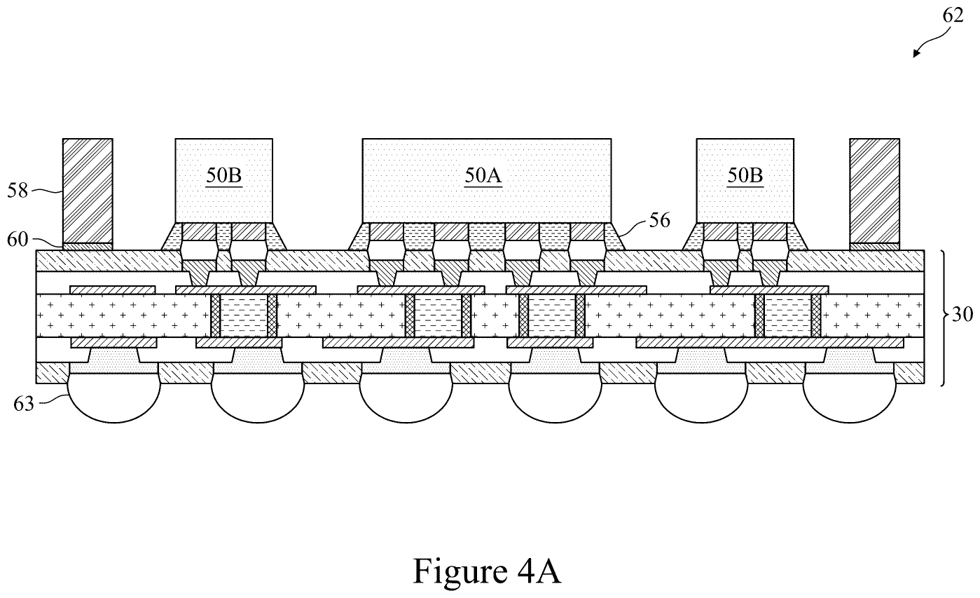

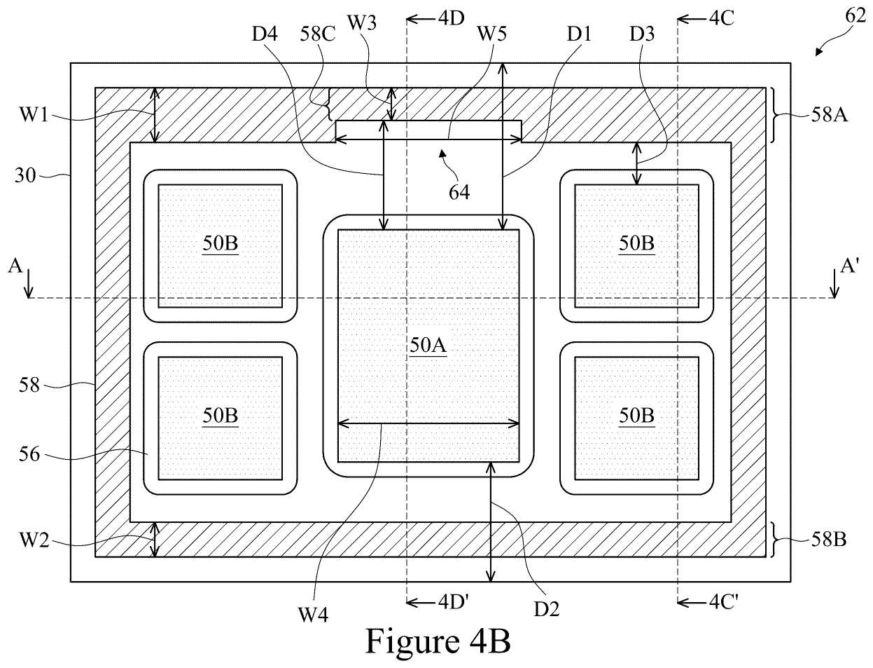

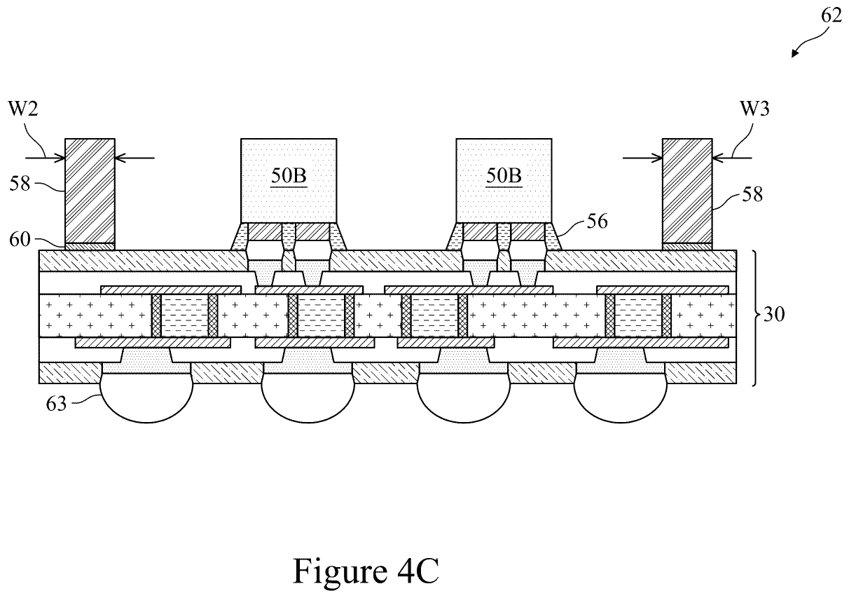

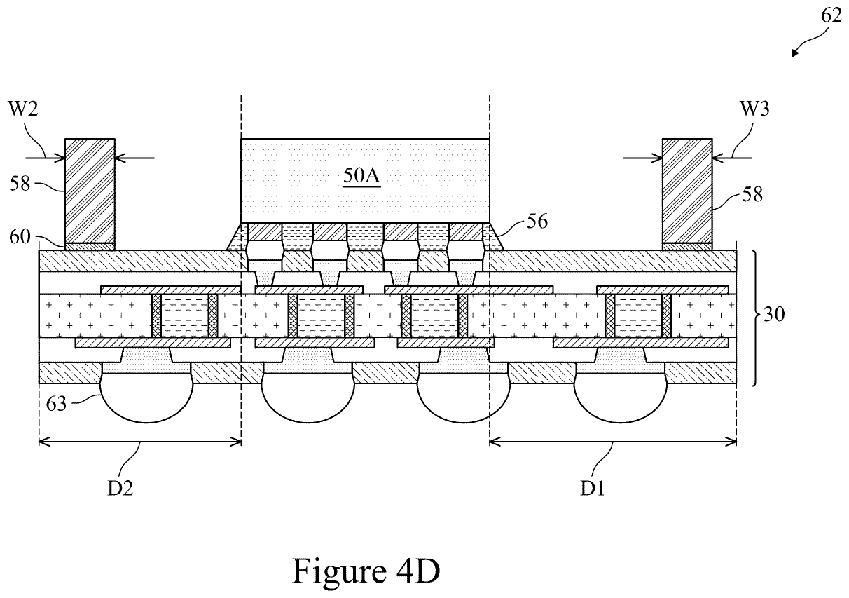

FIGS. 1 through 4A illustrate the cross-sectional views of the formation of semiconductor package 62 as shown in FIG. 4A. Referring to FIG. 1, substrate 30 is shown as a core substrate in accordance with some embodiments. The substrate 30 may be formed according to applicable manufacturing processes. For example, the substrate 30 may comprise a core material 32. The core material 32 may comprise one or more layers of glass fiber, resin, filler, pre-preg, epoxy, silica filler, Ajinomoto Build-up Film (ABF), polyimide, molding compound, other materials, and/or combinations thereof. The core material 32 may be formed of organic materials and/or inorganic materials. In some embodiments, the core material 32 may comprise one or more passive components (not shown) embedded inside.

Through vias 34 may be formed extending through the core material 32. The through vias 34 may comprise a conductive material such as copper, a copper alloy, or other conductors, and may include a barrier layer (not shown), liner (not shown), seed layer (not shown), and/or a fill material 36. The through vias 34 may provide vertical electrical connections from one side of the core material 32 to the other side of the core material 32. For example, some of the through vias 34 may be coupled between conductive features on one side of the core material 32 and conductive features on an opposite side of the core material 32. In some embodiments, openings for the through vias 34 may be formed in the core material 32 using a drilling process, a photolithography process, a laser process, or another suitable process. The openings for the through vias 34 may be filled or plated with conductive material. In some embodiments, the through vias 34 may have centers that are filled with a fill material 36, which may be insulating.

Redistribution structures 38 may be formed on opposing sides of the core material 32. The redistribution structures 38 may each comprise one or more dielectric layers 40, formed of ABF, pre-preg, or the like, and metallization patterns 42. Each respective metallization pattern 42 may have line portions on and extending along a major surface of a respective dielectric layer 40 and via portions (not shown) extending through the respective dielectric layer 40. The metallization patterns 42 of the redistribution structures 38 may be electrically coupled by the through vias 34. The redistribution structures 38 each may comprise under-bump metallurgies (UBMs) 44 for external connection, and solder resists 46 protecting the features of the redistribution structures 38. UBMs 44 may comprise, for example, nickel, copper, titanium, or multi-layers thereof. In some embodiments, each of UBMs 44 includes a titanium layer and a copper layer over the titanium layer. Each redistribution structure 38 of the substrate 30 may have more dielectric layers 40 and metallization patterns 42 than shown in FIG. 1.

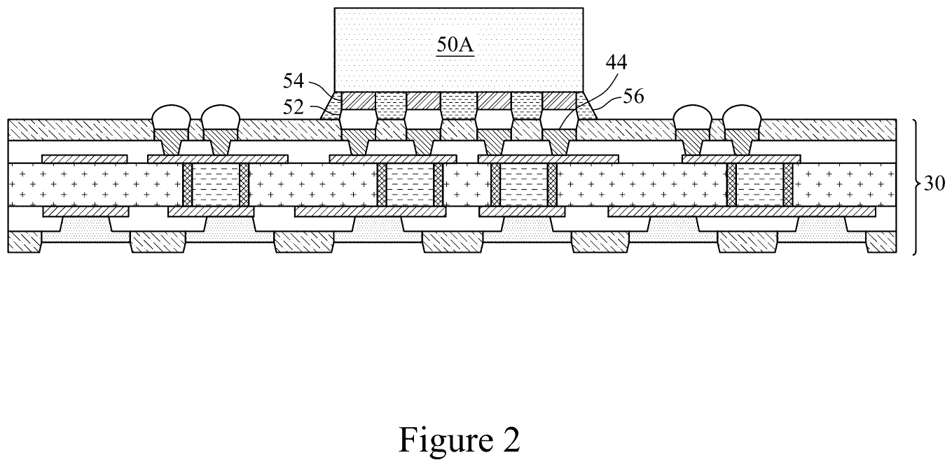

Referring to FIG. 2, package component 50A is bonded to the substrate 30, and underfill 56 is formed between the package component 50A and the substrate 30 in accordance with some embodiments. The two processes are illustrated as process 202 and 204, respectively, in the process flow 200 as shown in FIG. 10. In some embodiments, the package component 50A may comprise external connectors 54, where the package component 50A may be bonded to the substrate 30 by electrical connectors 52, such as solder. For example, solder may be placed on external connectors 54 or the UBMs 44, and a reflow process may be performed. External connectors 54 may also be non-solder metal pillars, or metal pillars with solder caps over the non-solder metal pillars, which may be formed through plating. Other types of bonding, such as metal-to-metal direct bonding, hybrid bonding (including both of dielectric-to-dielectric bonding and metal-to-metal direct bonding), or the like may also be used.

Underfill 56 is formed between the package component 50A and the substrate 30 to reduce stress and protect the joints between the package component 50A and the substrate 30, such as electrical connectors 52. In some embodiments, underfill 56 may include a base material, such as an epoxy, and filler particles in the epoxy, and may be deposited by a capillary flow process after the package component 50A is attached to the substrate 30 or may be formed by a suitable deposition method before the package component 50A is attached to the substrate 30. For example, underfill 56 may be dispensed from one side of the package component 50A, and flows into the gaps between the package component 50A and the substrate 30. Underfill 56 may be cured to harden.

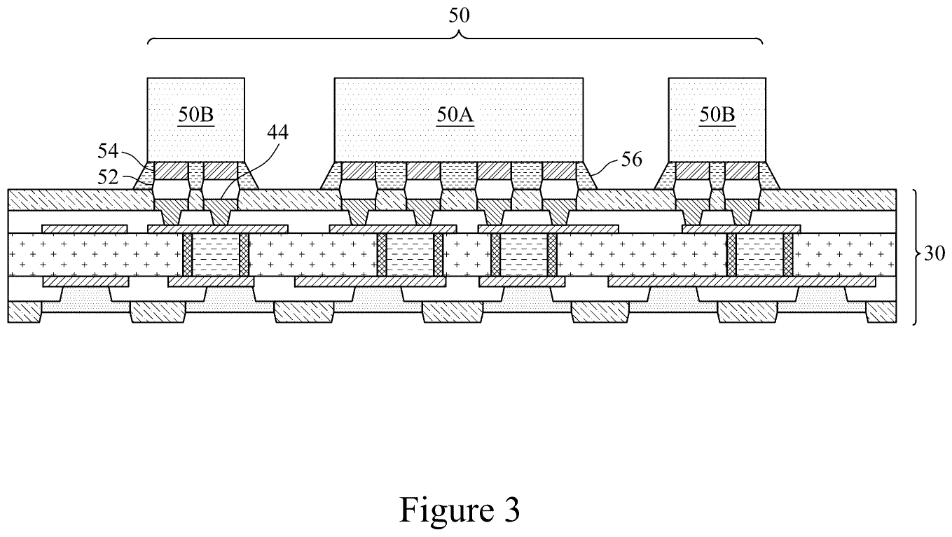

Referring to FIG. 3, package components 50B are bonded to the substrate 30, and the underfill 56 is formed between the package components 50B and the substrate 30 in accordance with some embodiments. The two processes are illustrated as process 206 and 208, respectively, in the process flow 200 as shown in FIG. 10. The bonding of the package components 50B and the substrate 30, and the formation of the underfill 56 may be performed using the same or similar processes as discussed above with reference to FIG. 2.

The numbers of the package component 50A and the package components 50B, and the relative locations of the package component 50A and the package components 50B shown in FIG. 3 are provided as an example. It should be appreciated that other numbers and other locations of the package component 50A and the package components 50B are possible. FIGS. 2 and 3 describe that the package component 50A is bonded to the substrate 30 before the package components 50B an example. It should be appreciated that the package components 50B may be bonded to the substrate 30 before the package components 50A or the package component 50A and the package components 50B are bonded to the substrate 30 at the same time.

Each of the package component 50A and the package components 50B may be a device die, a stack of device dies, a package with one or more device dies packaged therein, a System-on-Chip (SoC) die including a plurality of device dies packaged as a system, or the like. In some embodiments, the package component 50A and the package components 50B are or contain a same type of die. The device dies in the package component 50A and the package components 50B may be logic dies, memory dies, input-output dies, Integrated Passive Devices (IPDs), or the like, or combinations thereof. For example, the logic device dies in the package component 50A and the package components 50B may be Central Processing Unit (CPU) dies, Graphic Processing Unit (GPU) dies, mobile application dies, Micro Control Unit (MCU) dies, BaseBand (BB) dies, Application processor (AP) dies, power management integrated circuit (PMIC) dies, radio frequency (RF) dies, sensor dies, micro-electro-mechanical-system (MEMS) dies, digital signal processing (DSP) dies, analog front-end (AFE) dies, or the like. The memory dies in the package component 50A and the package components 50B may be Static Random Access Memory (SRAM) dies, Dynamic Random Access Memory (DRAM) dies, chip scale package (CSP), high bandwidth memory (HBM) or the like. In some embodiments, the package component 50A and the package components 50B are or contain different types of dies. For example, the package component 50A may be or contain logic dies, such as CPU or GPU, and the package components 50B may be or contain memory dies, such as DRAM, CSP, or HBM. The package component 50A and the package components 50B may be collectively referred to as package components 50.

Referring to FIG. 4A, stiffener ring 58 is attached to package the substrate 30 in accordance with some embodiments. The respective process is illustrated as process 210 in the process flow 200 as shown in FIG. 10. The stiffener ring 58 may be used to provide additional support to the substrate 30 during subsequent manufacturing processes and usage to reduce warpage or other types of deformation of the substrate 30. The stiffener ring 58 may be placed so that the stiffener ring 58 is laterally separated from the package components 50 and the underfill 56. The stiffener ring 58 may encircle the package components 50, thereby forming a cavity between the package components 50 and the stiffener ring 58 in a cross-sectional view. In some embodiments, the stiffener ring 58 may comprise a rigid material, such as a material with a Young's Modulus greater than 100 GPa. For example, the stiffener ring 58 may comprise a metal (e.g., copper, stainless steel, or other suitable metal), ceramic materials, organic materials, or the like. In some embodiments, the stiffener ring 58 may comprise a dielectric material. The stiffener ring 58 may be attached utilizing an adhesive 60 such as an epoxy, glue, polymeric material, solder paste, thermal adhesive, or the like. FIG. 4A shows the package component 50A, the package components 50B, and the stiffener ring 58 have the similar heights as an example. It should be appreciated that the package component 50A, the package components 50B, and the stiffener ring 58 may have different heights. Electrical connectors 63 may be formed on UBMs 44. Electrical connectors 63 may comprise solder, non-solder metal pillars, or metal pillars and solder caps over the non-solder metal pillars. The substrate 30 and all components bonded or attached to the substrate 30, such as the package components 50 and the stiffener ring 58, are collectively referred to as semiconductor package 62.

FIG. 4B shows a top view of the semiconductor package 62 shown in FIG. 4A, wherein the stiffener ring 58 encircles the package components 50. The cross-sectional view shown in FIGS. 1-4A may be obtained from the reference cross-section A-A′ in FIG. 4B. One package component 50A is disposed near the center of the substrate 30 and one package component 50B is disposed near each corner of the substrate 30. The numbers of the package component 50A and the package components 50B, and the relative locations of the package component 50A and the package components 50B shown in FIG. 4B are provided in accordance of some embodiments.

It should be appreciated that other numbers and other locations of the package component 50A and the package components 50B are possible.

Still referring to FIG. 4B, a top edge of the substrate 30 is spaced apart from a top edge of the package component 50A by a distance D1, which may be in a range between about 5 mm and about 50 mm, such as about 10 mm. FIG. 4B further illustrates a bottom edge of the substrate 30 spaced apart from a bottom edge of the package component 50A by a distance D2, which may be in a range between about 4 mm and about 40 mm, such as about 7 mm. In some embodiments, the distance D1 may be greater than the distance D2 and the package component 50A may be off-centered vertically with respect to the substrate 30. In some embodiments, the package component 50A may be centered laterally with respect to the substrate 30.

A top segment 58A of the stiffener ring 58 has a width W1, which may be in a range between about 2 mm and about 22 mm, such as about 5 mm. A bottom segment 58B of the stiffener ring 58 has a width W2, which may be in a range between about 1 mm and about 21 mm, such as about 3 mm. In some embodiments, the width W1 may be greater than the width W2, and the top segment 58A of the stiffener ring 58 may have a greater stiffness than the bottom segment 58B of the stiffener ring 58. A bottom edge of the top segment 58A of the stiffener ring 58 may be spaced apart from a top edge of the package component 50B by a distance D3, which may be in a range between about 1 mm and about 15 mm, such as about 3 mm.

Still referring to 4B, the top segment 58A of the stiffener ring 58 has a recess 64 that faces the package component 50A, and the recess 64 may be laterally centered about the package component 50A. The recessed portion of the stiffener ring 58C has a width W3, which may be in a range between about 0.5 mm and about 20 mm, such as about 4.5 mm. In some embodiments, the width W3 may be smaller than the width W1, and the recessed portion of the stiffener ring 58C may have a smaller stiffness than the thicker portions of the top segment 58A of the stiffener ring 58. A distance D4 may extend from a bottom of the recess 64 to a top edge of the package component 50A, wherein the distance D4 may be in a range between about 1.5 mm and about 20 mm, such as about 5.5 mm. In some embodiments, the distance D4 may be greater than a width W3. The package component 50A may have a width W4, which may be in a range between about 5 mm and about 35 mm, such as about 20 mm. The recess 64 may have a width W5, which may be in a range between about 5 mm and about 35 mm, such as about 20 mm. In some embodiments, the width W4 may be the same as the width W5. Since the recessed portion of the stiffener ring 58C may have a smaller stiffness than the thicker portions of the top segment 58A of the stiffener ring 58 and the recessed portion of the stiffener ring 58C may be laterally centered about the package component 50A, the recessed portion of the stiffener ring 58C may reduce the stress of the underfill 56 disposed between the package component 50A and the substrate 30, and along the top segment 58A of the stiffener ring 58, thereby reducing the cracking and/or delamination of the corner regions of the underfill 56 that face the recess 64. The reduction of cracking and/or delamination of the underfill 56 leads to better long-term reliability of the semiconductor package 62.

FIGS. 4C and 4D show another two cross-sectional views of semiconductor package 62 shown in FIGS. 4A and 4B, which may be obtained from the reference cross-section 4C-4C′ and reference cross-section 4D-4D′ in FIG. 4B, respectively, wherein like reference numerals refer to like features. In FIG. 4C, the stiffener ring 58 to the right of the package components 50B corresponds to the top segment 58A of the stiffener ring 58 in FIG. 4B with the width W1, and the stiffener ring 58 to the left of the package components 50B corresponds to the bottom segment 58B of the stiffener ring 58 in FIG. 4B with the width W2. In some embodiments, the width W1 may be greater than the width W2.

In FIG. 4D, the stiffener ring 58 to the right of the package component 50A corresponds to the recessed portion of the stiffener ring 58C having the width W3, and the stiffener ring 58 to the left of the package component 50A corresponds to the bottom segment 58B of the stiffener ring 58 in FIG. 4B having the width W2. In some embodiments, the width W3 shown in FIG. 4D may be smaller than the width W1 shown in FIG. 4C. FIG. 4D further illustrates the distance D1 as the distance between a right edge of the package component 50A and a right edge of the substrate 30, which corresponds to the distance between the top edge of the substrate 30 and a top edge of the package component 50A as shown in FIG. 4B, and the distance D2 as the distance between a left edge of the package component 50A and a left edge of the substrate 30, which correspond to the distance between the bottom edge of the substrate 30 and the bottom edge of the package component 50A as shown in FIG. 4B. In some embodiments, the distance D1 may be greater than the distance D2.

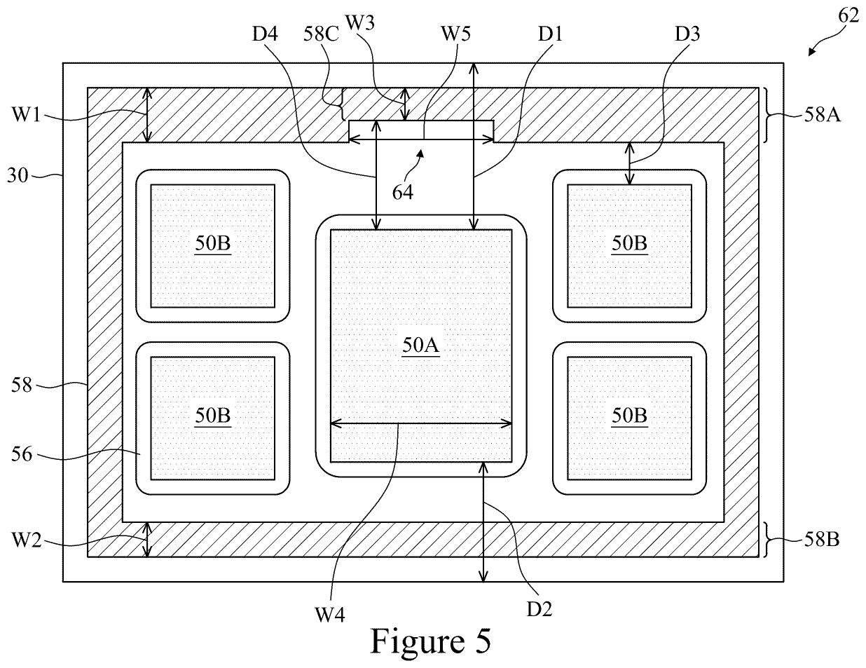

FIG. 5 illustrates a top view of a semiconductor package 62 similar to the one illustrated in FIG. 4B, wherein like reference numerals refer to like features. As shown in FIG. 5, the package component 50A has a width W4, which may be in a range between about 5 mm and about 35 mm, such as about 20 mm. The recess 64 has a width W5, which may be in a range between about 5 mm and about 35 mm, such as about 20 mm. In some embodiments, the width W4 of the package component 50A may be greater than as the width W5 of the recess 64.

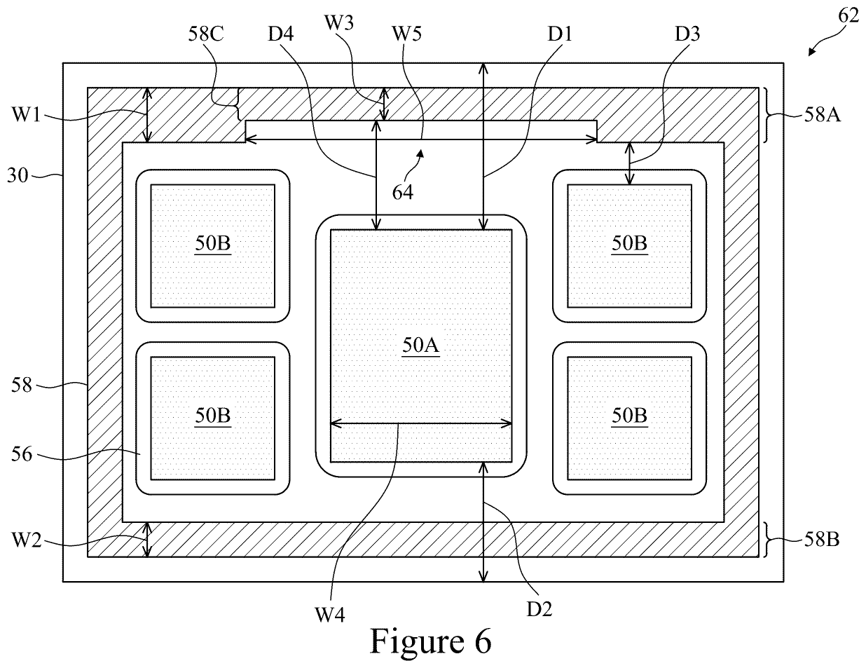

FIG. 6 illustrates a top view of a semiconductor package 62 similar to the one illustrated in FIG. 4B, wherein like reference numerals refer to like features. As shown in FIG. 6, the package component 50A has the width W4, which may be in a range between about 5 mm and about 35 mm, such as about 20 mm. The width W5 of the recess 64 may be in a range between about 5 mm and about 35 mm, such as about 20 mm. In some embodiments, the width W4 of the package component 50A may be smaller than the width W5 of the recess 64.

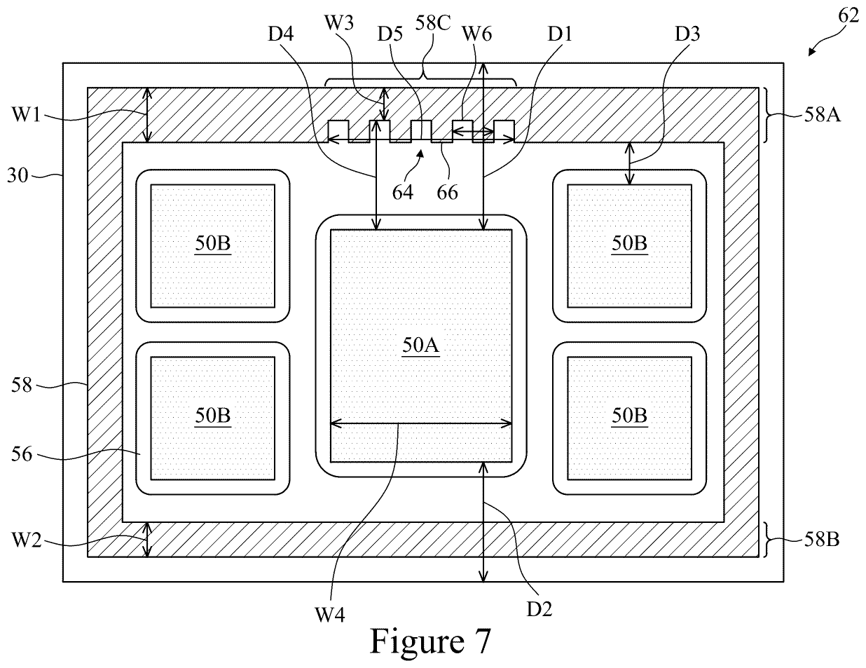

FIG. 7 illustrates a top view of a semiconductor package 62 similar to the one illustrated in FIG. 4B, wherein like reference numerals refer to like features. As shown in FIG. 7, the top segment 58A of the stiffener ring 58 has a plurality of recesses 64 that faces the package component 50A. A protrusion 66 is disposed between neighboring recesses 64. In some embodiments, all recesses 64 may have the same width, and all protrusions 66 may have the same width. In some embodiments, each recess 64 may have a different width and each protrusion 66 may have a different width. A sum of a width of one protrusion and one of the recesses 64 may have a width W6, which may be in a range between about 0.1 μm and about 5 μm, such as about 2 μm. A distance between a left sidewall of a recess 64 closest to a left edge of the substrate 30 and a right sidewall of a recess 64 closest to a right edge of the substrate 30 may be a distance D5, which may be in a range between about 5 mm and about 35 mm, such as about 20 mm. In other words, the distance D5 is the length of the recessed portion of the stiffener ring 58C, including the protrusions 66. The plurality of recesses 64 may be laterally centered about the package component 50A. The package component 50A may have the width W4, which may be in a range between about 5 mm and about 35 mm, such as about 20 mm. In some embodiments, the width W4 of the package component 50A may be the same as the distance D5 of the recesses 64, including the protrusions 66.

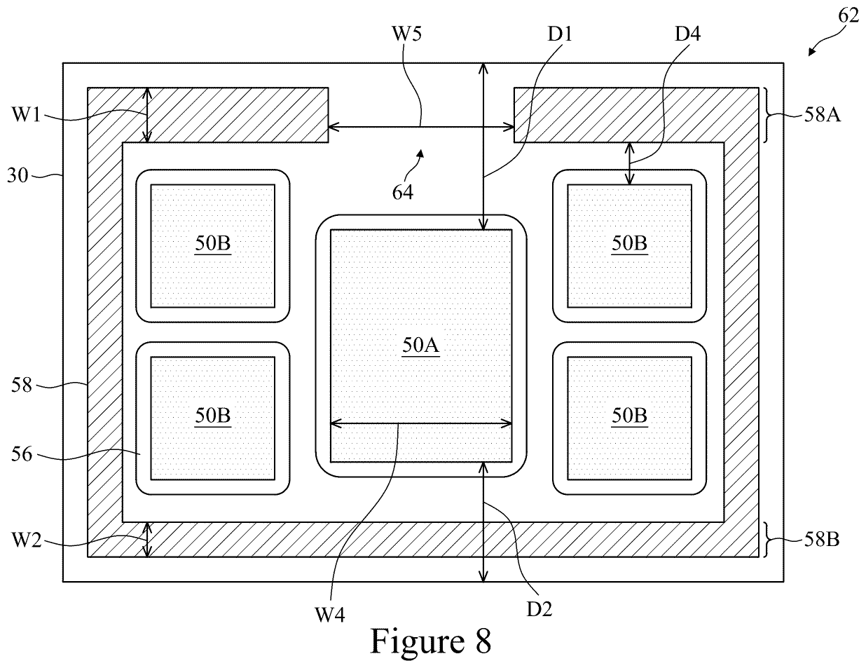

FIG. 8 illustrates a top view of a semiconductor package 62 similar to the one illustrated in FIG. 4B, wherein like reference numerals refer to like features. As shown in FIG. 8, the recess 64 extends completely through the top segment 58A of the stiffener ring 58, thereby forming an opening in the top segment 58A of the stiffener ring 58. The package component 50A has a width W4, which may be in a range between about 5 mm and about 35 mm, such as about 20 mm. The recess 64 has a width W5, which may be in a range between about 5 mm and about 35 mm, such as about 20 mm. In some embodiments, the width W4 of the package component 50A may be the same as the width W5 of the recess 64.

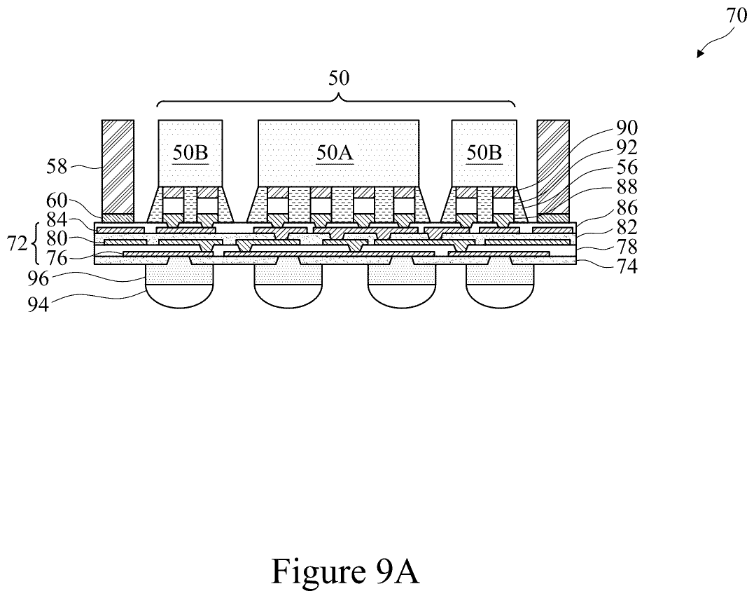

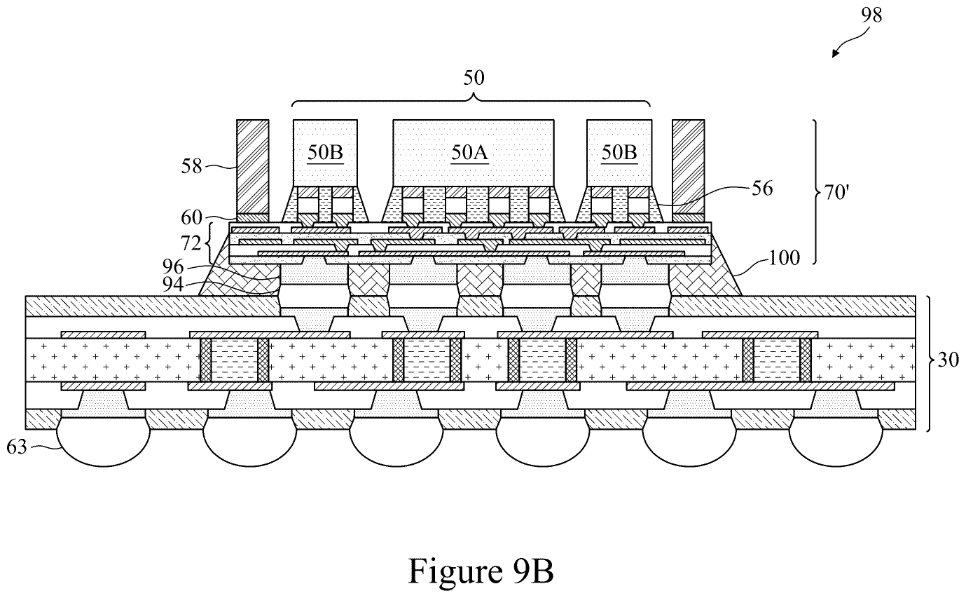

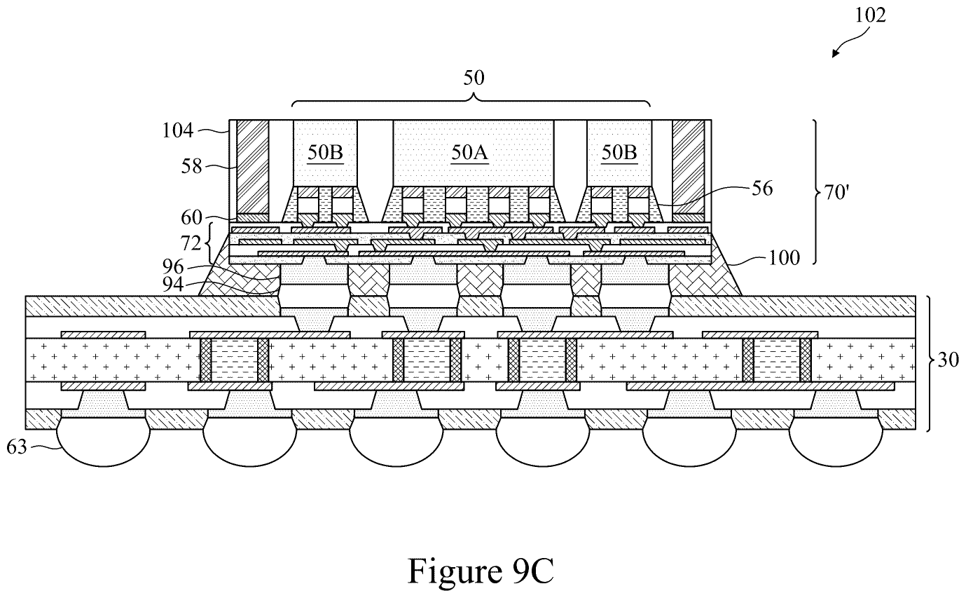

FIGS. 9A-9C illustrate various manufacturing steps in accordance with some embodiments. FIG. 9A shows a package component 70 similar to the one illustrated in FIG. 4A, wherein like reference numerals refer to like features. As shown in FIG. 9A, package components 50A and 50B are bonded to a coreless substrate 72.

For example, referring to FIG. 9A, the coreless substrate 72 may be formed by depositing an insulating layer 74 on a release film (not shown) over a carrier (not shown). The insulating layer 74 may be formed of or comprise an organic material, which may also be a photo-sensitive material, or an inorganic dielectric material. Redistribution lines (RDLs) 76 are formed over insulating layer 74. The formation of RDLs 76 may include forming a seed layer (not shown) over insulating layer 74, forming a patterned mask (not shown) such as a photoresist over the seed layer, and performing a plating process on the exposed seed layer. The patterned mask and the portions of the seed layer covered by the patterned mask are removed, leaving RDLs 76 as shown in FIG. 9A. The seed layer may be formed using Physical Vapor Deposition (PVD). The plating process may be performed using, for example, Electro Chemical Plating (ECP), electro-less plating, or the like. Insulating layer 78 is formed over the RDLs 76 and the insulating layer 74 using the same or similar materials and techniques used for forming the insulating layer 74. The insulating layer 78 is patterned to form openings and expose portions of RDLs 76 using an applicable photolithography process. RDLs 80 are formed over the insulating layer 78 using the same or similar materials and techniques used for forming RDLs 76. The RDLs 80 include metal lines over insulating layer 78 and metal vias extending into the openings in insulating layer 78 to connect to the RDLs 76. Insulating layer 82 is formed and patterned on the RDLs 80 and the insulating layer 78 using the same or similar materials and techniques used for forming insulating layer 78, and the RDLs 84 are formed using the same or similar materials and techniques used for forming RDLs 76. The RDLs 84 include metal lines over the insulating layer 82 and metal vias extending into the openings in the insulating layer 82 to connect to the RDLs 80. Insulating layer 86 is formed and patterned on the RDLs 84 and the insulating layer 82 using the same or similar materials and techniques used for forming the insulating layer 78. It is appreciated that three layers of RDLs (76, 80, and 84) are illustrated in FIG. 9A as an example, the coreless substrate 72 may have any number of RDL layers depending on the routing requirement.

Still referring to FIG. 9A, UBMs 88 are formed in the openings in the insulating layer 86. The UBMs 88 may be formed by depositing a seed layer (not shown) and a patterned mask layer (not shown) over the seed layer, and performing a plating process. UBMs 88 may be formed of or comprise nickel, copper, titanium, or multi-layers thereof. The package components 50A and 50B are bonded to the coreless substrate 72 via external connectors 90 and electrical connectors 92, such as solder. For example, solder may be placed on the external connectors 90 or the UBMs 88 and a reflow process performed. The electrical connectors 92 may also be non-solder metal pillars, or metal pillars and solder caps over the non-solder metal pillars, which may be formed through plating. Underfill 56 is placed between the package components 50A and 50B and the coreless substrate 72. The underfill 56 may include a base material, such as an epoxy, and filler particles in the epoxy, and may be deposited by a capillary flow process. Underfill 56 may be cured. Stiffener ring 58 is attached to the coreless substrate 72 utilizing an adhesive 60 such as an epoxy, glue, polymeric material, solder paste, thermal adhesive, or the like. In some embodiments, the stiffener ring 58 may have the same or similar structures as described with respect with FIGS. 4B, 5, 6, 7, and 8.

A carrier swap process is performed to reveal the bottom surface of the insulating layer 74, which is patterned to form openings that reveal portions of RDLs 76. UBMs 96 are formed in the openings in insulating layer 74 using the same or similar materials and techniques used for forming UBMs 88. Electrical connectors 94 are formed on UBMs 96 using the same or similar materials and techniques used for forming electrical connectors 92.

Referring to FIG. 9B, the package structure 70′ is attached to the substrate 30 to form package 98 via electrical connectors 94. The processes described above may be performed on a wafer level. For example, the coreless substrate 72 may be a wafer-level substrate and then singulated to form discrete package structures 70′ to be mounted on another substrate (e.g., package substrate, printed circuit board, or the like) as illustrated in FIG. 9B. In this example, the discrete package structure 70′ is attached to the substrate 30. Underfill 86 may be dispensed into the gap between package structure 64′ and package component 82. Underfill 100 is placed between the package structure 70′ and the substrate 30. The underfill 100 may comprise the same or similar materials as the underfill 56. The underfill 100 may be cured. FIG. 9C shows a package 102 similar to the package 98 shown in FIG. 9B, wherein like reference numerals refer to like features. In package 102, the package components 50A and 50B, and the stiffener ring 58 are encapsulated in encapsulant 104, which may be formed of or comprises a molding compound, a molding underfill, an epoxy, a resin, or the like.

The embodiments of the present disclosure have some advantageous features. By including the stiffener ring 58 in the semiconductor package 62, wherein the recess 64 is disposed in the top segment 58A of the stiffener ring 58, not only may the warpage or other types of deformation of the substrate 30 be reduced, but also the cracking and/or delamination of the corner regions of the underfill 56 that face the recess 64 may be reduced. The reduction of the warpage or other types of deformation of the substrate 30 and the cracking and/or delamination of the underfill 56 both lead to better long-term reliability of semiconductor package 62.

In an embodiment, a semiconductor package includes a substrate comprising a first edge and a second edge opposite the first edge; a package component bonded to the substrate, wherein the package component comprises a semiconductor die, wherein a first edge of the package component is a closest edge of the package component to the first edge of the substrate; an underfill between the package component and the substrate; and a ring structure attached to the substrate, wherein the ring structure encircles the package component in a top view, the ring structure comprising: a first segment extending along the first edge of the substrate, wherein the first segment has a first width, the first width being a distance between an outer edge of the first segment and an inner edge of the first segment, wherein the first segment comprises a recess extending at least partially through the ring structure, and wherein the recess faces the first edge of the package component in the top view. In an embodiment, the first edge of the package component and the first edge of the substrate are spaced apart by a first distance, wherein a second edge of the package component is a closest edge of the package component to the second edge of the substrate, wherein the second edge of the package component and the second edge of the substrate are spaced apart by a second distance, wherein the first distance is greater than the second distance. In an embodiment, the ring structure further comprises a second segment extending along the second edge of the substrate, the second segment having a second width, wherein the second width is a distance between an outer edge of the second segment and an inner edge of the second segment, wherein the first width is greater than the second width. In an embodiment, wherein the first segment has a second width, wherein the second width is a distance between the outer edge of the first segment and a bottom of the recess, wherein the first edge of the package component and the bottom of the recess are spaced apart by a first distance, wherein the first distance is greater than the second width. In an embodiment, the recess extends completely through the first segment. In an embodiment, the recess is one of a plurality of recesses in the first segment, wherein the plurality of recesses faces the first edge of the package component in the top view, wherein the plurality of recesses extends at least partially through the first segment. In an embodiment, each of the plurality of recesses has a same width, and wherein each of the plurality of recesses is spaced apart from a neighboring recess by a same distance. In an embodiment, the plurality of recesses is laterally centered about the package component in the top view.

In an embodiment, a semiconductor package includes a substrate; a package component bonded to the substrate, wherein the package component comprises a semiconductor die; an underfill between the package component and the substrate; and a frame structure attached to the substrate, wherein the frame structure encloses the package component in a top view, the frame structure comprising: a first bar along a first edge of the substrate, wherein the first bar comprises a first portion having a first width, a second portion having a second width, and a third portion having the first width, wherein the first width is greater than the second width, wherein the second portion is disposed between the first portion and the third portion, and wherein a closest edge of the second portion to the first edge of the substrate is level with a closest edge of the first portion to the first edge of the substrate and a closest edge of the third portion to the first edge of the substrate. In an embodiment, a first edge of the package component and the first edge of the substrate are spaced apart by a first distance, wherein a second edge of the package component and a second edge of the substrate are spaced apart by a second distance, wherein the first distance is greater than the second distance. In an embodiment, the frame structure further comprises a second bar along a second edge of the substrate, wherein the second bar has a uniform third width, wherein the first width is greater than the third width. In an embodiment, the first edge of the package component and a closest edge of the second portion to the first edge of the package component are spaced apart by a first distance, wherein the first distance is greater than the second width. In an embodiment, the second portion is laterally centered about the package component.

In an embodiment, a method of manufacturing a semiconductor package, the method includes bonding one or more package components to a substrate, wherein the one or more package components comprise one or more semiconductor dies, wherein a first package component of the one or more package components is disposed at a center of the substrate, wherein the substrate comprises a first edge and a second edge opposite the first edge, and wherein a first edge of the first package component is a closest edge of the first package component to the first edge of the substrate; placing an underfill between the one or more package components and the substrate; and attaching a ring structure to the substrate, wherein the ring structure encircles the one or more package components in a top view, the ring structure comprising: a first segment extending along the first edge of the substrate, wherein the first segment has a first width, the first width being a distance between an outer edge of the first segment and an inner edge of the first segment, wherein the first segment comprises an indentation extending at least partially through the ring structure, and wherein the indentation opens towards the first edge of the package component in the top view. In an embodiment, the first edge of the first package component is closer to the first edge of the substrate than a second edge of the first package component is to a second edge of the substrate. In an embodiment, the ring structure further comprises a second segment opposite the first segment, a width of the second segment being less than the first width. In an embodiment, the first segment further comprises one or more additional indentations. In an embodiment, the indentation forms an opening in the first segment. In an embodiment, the indentation is laterally centered about the first package component in the top view. In an embodiment, one or more additional package components of the one or more package components are disposed near corners of the substrate.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of manufacturing a semiconductor package, the method comprising:
bonding one or more package components to a substrate, wherein a first package component of the one or more package components is disposed at a center of the substrate, wherein the first package component comprises a first semiconductor die, wherein the substrate comprises a first edge and a second edge opposite the first edge, wherein a first edge of the first package component is a closest edge of the first package component to the first edge of the substrate, and wherein a second edge of the first package component is a closest edge of the first package component to the second edge of the substrate;
placing a first underfill between the first package component and the substrate, wherein the first underfill encircles the first package component in a top-down view; and
attaching a ring structure to the substrate, wherein the ring structure encircles the one or more package components in the top-down view, the ring structure comprising:
a first segment extending along the first edge of the substrate, wherein the first segment has a first width and a first length, wherein the first width is a distance between an outer edge of the first segment and an inner edge of the first segment, wherein the first segment comprises a first indentation extending at least partially through the ring structure, and wherein the first indentation opens towards the first edge of the first package component in the top-down view;
a second segment extending along the second edge of the substrate, wherein the second segment has a second width and a second length, wherein the second width is a distance between an outer edge of the second segment and an inner edge of the second segment; and
a third segment connecting the first segment and the second segment, wherein the third segment has a third width and a third length, wherein the third width is a distance between an outer edge of the third segment and an inner edge of the third segment, and wherein the third length is greater than the first length and the second length.

2. The method of claim 1, wherein the first edge of the first package component is closer to the first edge of the substrate than the second edge of the first package component is to the second edge of the substrate.

3. The method of claim 1, wherein the second width is less than the first width.

4. The method of claim 1, wherein the first segment further comprises one or more additional indentations adjacent the first indentation.

5. The method of claim 1, further comprising forming an encapsulant over the substrate, wherein the encapsulant is between the ring structure and the first package component.

6. The method of claim 1, wherein the first indentation is laterally centered about the first package component in the top-down view.

7. The method of claim 6, wherein sidewalls of the indentation are laterally between sidewalls of the first underfill in the top-down view.

8. A method of manufacturing a semiconductor package, the method comprising:
bonding one or more package components to a substrate, wherein a first package component of the one or more package components is disposed at a center of the substrate, wherein the first package component comprises a first semiconductor die, wherein a second package component of the one or more package components is disposed adjacent the first package component, and wherein the second package component comprises a second semiconductor die;
placing a first underfill between the first package component and the substrate, wherein the first underfill encircles the first package component in a top-down view;
placing a second underfill between the second package component and the substrate, wherein the second underfill encircles the second package component in the top-down view; and
attaching a ring structure to the substrate, wherein the ring structure encircles the one or more package components in the top-down view, the ring structure comprising:
a first segment, wherein the first segment comprises a first indentation extending at least partially through the ring structure, wherein the first indentation is laterally overlapping with the first package component in the top-down view, and wherein the first indentation is laterally non-overlapping with the second package component in the top-down view.

9. The method of claim 8, wherein the substrate comprises a first edge and a second edge opposite the first edge, wherein the first segment extends along the first edge of the substrate, wherein the first segment has a first width and a first length, wherein a second segment of the ring structure extends along the second edge of the substrate, wherein the second segment has a second width and a second length, and wherein the first width is greater than the second width.

10. The method of claim 9, wherein a first edge of the first package component is a closest edge of the first package component to the first edge of the substrate, wherein a second edge of the first package component is a closest edge of the first package component to the second edge of the substrate, wherein the first edge of the first package component and the first edge of the substrate are spaced apart by a first distance, wherein the second edge of the first package component and the second edge of the substrate are spaced apart by a second distance, and wherein the first distance is greater than the second distance.

11. The method of claim 10, wherein the first segment has a third width, wherein the third width is a distance between an outer edge of the first segment and a bottom of the first indentation, wherein the first edge of the first package component and the bottom of the first indentation are spaced apart by a third distance, and wherein the third distance is greater than the third width.

12. The method of claim 9, wherein a third segment of the ring structure connects the first segment and the second segment, wherein the third segment has a third width and a third length, and wherein the third length is greater than the first length and the second length.

13. The method of claim 8, wherein the first indentation is one of a plurality of indentations in the first segment, wherein the plurality of indentations faces the first package component in the top-down view.

14. The method of claim 8, wherein the first indentation is laterally centered about the first package component in the top-down view, and wherein the first package component is wider than the first indentation.

15. A method of manufacturing a semiconductor package, the method comprising:
bonding first package component and a second package component to a substrate, wherein the first package component comprises a first semiconductor die and the second package component comprises a second semiconductor die, wherein the first package component comprises a first sidewall, a second sidewall, and a third sidewall, and wherein the third sidewall is connected to the first sidewall and the second sidewall;
placing a first underfill between the first package component and the substrate, wherein the first underfill encircles the first package component in a top-down view;
placing a second underfill between the second package component and the substrate, wherein the second underfill encircles the second package component in the top-down view; and
attaching a ring structure to the substrate, wherein the ring structure encircles the first package component and the second package component in the top-down view, the ring structure comprising:
a first segment, wherein the first segment comprises a first recess facing the third sidewall of the first package component, wherein the first recess comprises a fourth sidewall and a fifth sidewall, wherein the fourth sidewall faces the fifth sidewall, and wherein the fourth sidewall and the fifth sidewall of the first recess are laterally between the first sidewall and the second sidewall of the first package component.

16. The method of claim 15, wherein the first recess is laterally overlapping with the first underfill in the top-down view, and wherein the first recess is laterally non-overlapping with the second underfill in the top-down view.

17. The method of claim 15, wherein the first recess is one of a plurality of recesses in the first segment, and wherein the plurality of recesses faces the third sidewall of the first package component in the top-down view.

18. The method of claim 17, wherein each of the plurality of recesses has a same width, and wherein each of the plurality of recesses is spaced apart from a neighboring recess by a same distance.

19. The method of claim 17, wherein the plurality of recesses is laterally centered about the first package component in the top-down view.

20. The method of claim 14, further comprising forming an encapsulant over the substrate, wherein the encapsulant is on an outer sidewall of the ring structure.
